(19) United States
(12) Patent Application Publication
(10) Pub. No.: US 2024/0313724 A1
(43) Pub. Date: Sep. 19, 2024

(54) AMPLIFICATION DEVICE

(71) Applicant: Murata Manufacturing Co., Ltd., Kyoto-fu (JP)

(72) Inventors: Masao KONDO, Nagaokakyo-shi (JP); Takayuki TSUTSUI, Nagaokakyo-shi (JP); Satoshi GOTO, Nagaokakyo-shi (JP)

(73) Assignee: Murata Manufacturing Co., Ltd., Kyoto-fu (JP)

(21) Appl. No.: 18/671,143

(22) Filed: May 22, 2024

Related U.S. Application Data
(63) Continuation of application No. PCT/JP2022/039395, filed on Oct. 21, 2022.

(30) Foreign Application Priority Data
Dec. 8, 2021 (JP) 2021-199324

(51) Int. Cl. H03F 3/45; H01P 5/12

(52) U.S. Cl. CPC H03F 3/45475; H01P 5/12; H03F 2200/06

(57) ABSTRACT

A first differential amplifier circuit is in or on a substrate and includes a pair of differential input nodes to which differential signals are input and a pair of differential output nodes from which differential signals are output. Ends of a secondary coil of a first transformer are connected to the pair of differential input nodes of the first differential amplifier circuit, and an intermediate point of the secondary coil is AC grounded. Ends of a primary coil of a second transformer are connected to the pair of differential output nodes of the first differential amplifier circuit, and an intermediate point of the primary coil of the second transformer is AC grounded. A differential wire pair connects the ends of the secondary coil of the first transformer to the pair of differential input nodes of the first differential amplifier circuit.

### CROSS-REFERENCE TO RELATED APPLICATIONS

This application claims benefit of priority to International Patent Application No. PCT/JP2022/039395, filed Oct. 21, 2022, and to Japanese Patent Application No. 2021-199324, filed Dec. 8, 2021, the entire contents of each are incorporated herein by reference.

### BACKGROUND

### Technical Field

The present disclosure relates to an amplification device.

### Background Art

U.S. Pat. No. 9,584,076 discloses a circuit that uses a differential amplifier to amplify a single-ended signal. The amplifier circuit disclosed in U.S. Pat. No. 9,584,076 includes an input-side balun transformer that converts a single-ended signal into differential signals and inputs the differential signals to a differential amplifier, and an output-side balun transformer that converts the differential signals amplified by the differential amplifier into a single-ended signal. Generally, the input-side balun transformer is connected to the differential amplifier, and the output-side balun transformer is connected to the differential amplifier, each via the shortest path to minimize the line length.

### SUMMARY

There is a case in which the output-side balun transformer and the input-side balun transformer are magnetically coupled to each other. If a positive feedback is applied from the output-side balun transformer to the input-side balun transformer as a result of the magnetic coupling, the differential amplifier may oscillate. Accordingly, the present disclosure provides an amplification device configured to suppress oscillation.

An aspect of the present disclosure provides an amplification device that includes a substrate; a first differential amplifier circuit that is disposed in or on the substrate and includes a pair of differential input nodes to which differential signals are input and a pair of differential output nodes from which differential signals are output; a first transformer that includes a primary coil and a secondary coil, with ends of the secondary coil of the first transformer being connected to the pair of differential input nodes of the first differential amplifier circuit, and an intermediate point of the secondary coil of the first transformer being AC grounded; and a second transformer that includes a primary coil and a secondary coil, with ends of the primary coil of the second transformer being connected to the pair of differential output nodes of the first differential amplifier circuit, and an intermediate point of the primary coil of the second transformer being AC grounded. A differential wire pair connects the ends of the secondary coil of the first transformer to the pair of differential input nodes of the first differential amplifier circuit, and another differential wire pair connects the pair of differential output nodes of the first differential amplifier circuit to the ends of the primary coil of the second transformer. In plan view of the substrate, two wires of one of the differential wire pairs intersect with each other, and two wires of another one of the differential wire pairs do not intersect with each other.

Another aspect of the present disclosure provides an amplification device that includes a substrate; multiple amplifier circuits each of which includes an input node and an output node; a power distribution circuit that includes one input wire and multiple output wires, with one end of the input wire being grounded, a single-ended signal being input to another end of the input wire, an intermediate point of each of the multiple output wires being grounded, and the power distribution circuit being configured to output the single-ended signal input to the input wire as differential signals from ends of each of the multiple output wires and to input the differential signals to input nodes of two amplifier circuits selected from the multiple amplifier circuits; and a power combining circuit that combines multiple differential signals output from the multiple amplifier circuits into one single-ended signal. The multiple output wires of the power distribution circuit are laid out along an annular shape in plan view of the substrate. The multiple amplifier circuits are arranged in a circumferential direction of the annular shape along which the multiple output wires of the power distribution circuit are laid out. When an upstream end and a downstream end of each of the multiple output wires in one circumferential direction of the annular shape, along which the multiple output wires of the power distribution circuit are laid out, are referred to as a first end and a second end, multiple first ends and multiple second ends of the multiple output wires are arranged in the circumferential direction. The amplification device further comprises multiple cross wire pairs each of which connects the first end and the second end, which are among the multiple first ends and the multiple second ends and adjacent to each other in the circumferential direction, to two input nodes that are among the input nodes of the multiple amplifier circuits and adjacent to each other in the circumferential direction. Also, each of the multiple cross wire pairs includes two wires that intersect with each other in plan view of the substrate.

When a positive feedback is applied in a condition in which the two wires of each of the differential wire pair connecting the first transformer to the first differential amplifier circuit and the differential wire pair connecting the first differential amplifier circuit to the second transformer do not intersect with each other, it is possible to apply a negative feedback by arranging the two wires of one of the differential wire pairs to intersect with each other. This in turn makes it possible to suppress oscillation.

When a positive feedback is applied in a condition in which the two wires of each of the multiple cross wire pairs do not intersect with each other, it is possible to apply a negative feedback by arranging the two wires of each of the multiple cross wire pairs to intersect with each other. This in turn makes it possible to suppress oscillation.

### BRIEF DESCRIPTION OF THE DRAWINGS

FIG. 1A is an equivalent circuit diagram of an amplification device according to a first embodiment, and FIG. 1B is an equivalent circuit diagram of an amplification device according to a comparative example.

FIG. 2A, FIG. 2B, and FIG. 2C are equivalent circuit diagrams of amplification devices according to variations of the first embodiment;

FIG. 3 is an equivalent circuit diagram of an amplification device according to a second embodiment;

FIG. 4 is an equivalent circuit diagram of an amplification device according to a third embodiment;

FIG. 5 is a schematic diagram illustrating the amplification device of the third embodiment with a focus on the planar shapes and the positional relationship of a first transformer and a second transformer;

FIG. 6 is a schematic diagram illustrating the amplification device according to the comparative example with a focus on the planar shapes and the positional relationship of a first transformer and a second transformer;

FIG. 7 is a schematic diagram illustrating an amplification device according to a variation of the third embodiment with a focus on the planar shapes and the positional relationship of a first transformer and a second transformer;

FIG. 8 is a schematic diagram illustrating an amplification device according to another variation of the third embodiment with a focus on the planar shapes and the positional relationship of a first transformer and a second transformer;

FIG. 9 is an equivalent circuit diagram of an amplification device according to a fourth embodiment;

FIG. 10 is a schematic diagram illustrating the amplification device according to the fourth embodiment with a focus on the planar shapes and the positional relationship of a first transformer, a second transformer, and a downstream transformer.

FIG. 11 is a schematic diagram illustrating an amplification device according to a variation of the fourth embodiment with a focus on the planar shapes and the positional relationship of a first transformer, a second transformer, and a downstream transformer;

FIG. 12 is an equivalent circuit diagram of an amplification device according to a fifth embodiment;

FIG. 13 is a schematic diagram illustrating the amplification device according to the fifth embodiment with a focus on the planar shapes and the positional relationship of an upstream transformer, a first transformer, and a second transformer;

FIG. 14 is an equivalent circuit diagram of an amplification device according to a sixth embodiment;

FIG. 15 is a schematic diagram illustrating the amplification device according to the sixth embodiment with a focus on the planar shapes and the positional relationship of an upstream transformer, a first transformer, and a second transformer;

FIG. 16 is an equivalent circuit diagram of an amplification device according to a seventh embodiment;

FIG. 17 is a schematic diagram illustrating the amplification device according to the seventh embodiment with a focus on the planar shapes and the positional relationship of a power distribution circuit and a power combining circuit;

FIG. 18 is a schematic diagram illustrating an amplification device according to a variation of the seventh embodiment with a focus on the planar shapes and the positional relationship of a power distribution circuit and a power combining circuit;

FIG. 19 is an equivalent circuit diagram of an amplification device according to an eighth embodiment;

FIG. 20 is a schematic diagram illustrating the amplification device according to the eighth embodiment with a focus on the planar shapes and the positional relationship of a power distribution circuit and a power combining circuit; and

FIG. 21 is a schematic diagram illustrating an amplification device according to a variation of the eighth embodiment with a focus on the planar shapes and the positional relationship of a power distribution circuit and a power combining circuit.

### DETAILED DESCRIPTION

### First Embodiment

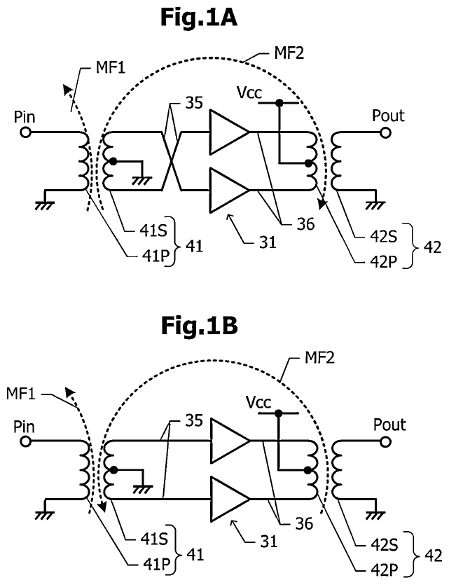

An amplification device according to a first embodiment is described with reference to FIG. 1A.

FIG. 1A is an equivalent circuit diagram of the amplification device according to the first embodiment. The amplification device according to the first embodiment includes a first transformer 41, a first differential amplifier circuit 31, and a second transformer 42. The first transformer 41 is a balun transformer that converts a single-ended signal into differential signals, and the second transformer 42 is a balun transformer that converts differential signals into a single-ended signal. The first differential amplifier circuit 31 includes a pair of differential input nodes to which differential signals are input and a pair of differential output nodes from which differential signals are output.

The first transformer 41 includes a primary coil 41P and a secondary coil 41S. A single-ended signal Pin is input to the primary coil 41P. An intermediate point of the secondary coil 41S is grounded. Ends of the secondary coil 41S are connected to the pair of differential input nodes of the first differential amplifier circuit 31 via two wires of a differential wire pair 35. The two wires of the differential wire pair 35 intersect with each other. For example, when the differential wire pair 35 is formed on a semiconductor substrate or a module substrate, the two wires intersect with each other in plan view of the substrate. In the equivalent circuit diagram illustrated in FIG. 1A, the positional relationship between the intersecting two wires in plan view of the substrate is represented by intersecting straight lines corresponding to the wires.

The second transformer 42 includes a primary coil 42P and a secondary coil 42S. Ends of the primary coil 42P are connected to the pair of differential output nodes of the first differential amplifier circuit 31 via two wires of a differential wire pair 36. The two wires of the differential wire pair 36 do not intersect with each other. An intermediate point of the primary coil 42P is connected to a power supply voltage Vcc and is AC grounded. Power is supplied to the first differential amplifier circuit 31 via the primary coil 42P and the differential wire pair 36. An amplified single-ended signal Pout is output from the secondary coil 42S of the second transformer 42.

Next, an advantageous effect of the first embodiment is described in comparison with a comparative example illustrated in FIG. 1B.

FIG. 1B is an equivalent circuit diagram of an amplification device according to a comparative example. In the comparative example, the two wires of the differential wire pair 35 connecting the secondary coil 41S of the first transformer 41 to the first differential amplifier circuit 31 do not intersect with each other. Other configurations are the same as those of the amplification device according to the first embodiment.

A magnetic flux MF1 is generated by an electric current flowing through the first transformer 41, and a magnetic flux MF2 is generated by an electric current flowing through the second transformer 42. When the magnetic flux MF2 is interlinked with the first transformer 41, a part of the output of the first differential amplifier circuit 31 is fed back to the input.

The phase relationship between the magnetic flux MF1 and the magnetic flux MF2 depends on the phase characteristics of the first differential amplifier circuit 31 and the influence of, for example, a capacitor disposed in a transmission line extending from the first transformer 41 to the second transformer 42. As illustrated in FIG. 1B, at the position of the first transformer 41, when the phase of the magnetic flux MF2 is the opposite of the phase of the magnetic flux MF1, the direction of an induction current flowing through the first transformer 41 as a result of a change in the magnetic flux MF2 becomes the same as the direction of an original electric current. As a result, a positive feedback is applied from the output side to the input side of the first differential amplifier circuit 31, and oscillation may occur.

As illustrated in FIG. 1A, with the configuration in which the two wires of the differential wire pair 35 intersect with each other, the phase relationship between the magnetic flux MF1 and the magnetic flux MF is opposite to that in the comparative example of FIG. 1B. That is, at the position of the first transformer 41, the phase of the magnetic flux MF2 is the same as the phase of the magnetic flux MF1. In this case, the direction of an induction current flowing through the first transformer 41 as a result of a change in the magnetic flux MF2 becomes the opposite of the direction of an original electric current. As a result, a negative feedback is applied from the output side to the input side of the first differential amplifier circuit 31. This provides an advantageous effect of suppressing the occurrence of oscillation.

Here, when each of the differential wire pair 35 on the input side of the first differential amplifier circuit 31 and the differential wire pair 36 on the output side of the first differential amplifier circuit 31 is configured such that the two wires intersect with each other, the state of the feedback from the output side to the input side is the same as that in the configuration of FIG. 1B in which each of the differential wire pair 35 and the differential wire pair 36 is configured such that the two wires do not intersect with each other. Thus, the above-described advantageous effect can be achieved with the configuration of the first embodiment in which the two wires of the differential wire pair 35 on the input side of the first differential amplifier circuit 31 intersect with each other, and the two wires of the differential wire pair 36 on the output side of the first differential amplifier circuit 31 do not intersect with each other.

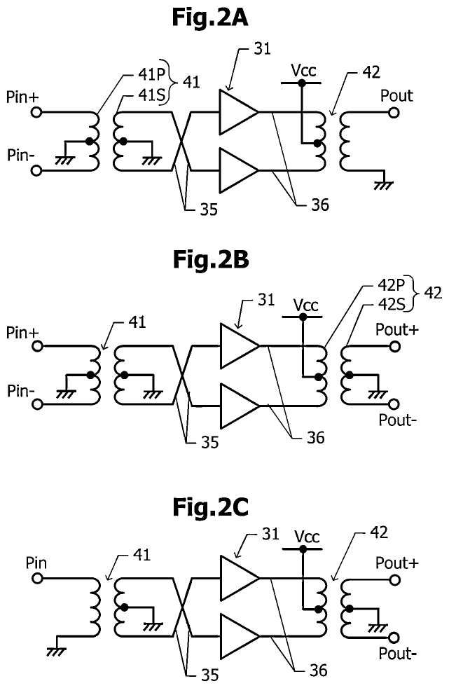

Next, amplification devices according to variations of the first embodiment are described with reference to FIGS. 2A, 2B, and 2C. FIGS. 2A, 2B, and 2C are equivalent circuit diagrams of amplification devices according to variations of the first embodiment.

In the first embodiment (FIG. 1A), each of the first transformer 41 and the second transformer 42 is a balun transformer that performs conversion between a single-ended signal and differential signals. On the other hand, in the variation illustrated in FIG. 2A, the first transformer 41 is a differential transformer that performs impedance conversion of differential signals. An intermediate point of each of the primary coil 41P and the secondary coil 41S of the first transformer 41 is grounded. Differential signals Pin+ and Pin− are input to the ends of the primary coil 41P, and the differential signals are output from the ends of the secondary coil 41S. The amplification device of this variation amplifies the differential signals Pin+ and Pin− and outputs a single-ended signal Pout.

In the variation illustrated in FIG. 2B, each of the first transformer 41 and the second transformer 42 is a differential transformer. An intermediate point of the secondary coil 42S of the second transformer 42 is grounded. Differential signals output from the first differential amplifier circuit 31 are impedance-converted by the second transformer 42 and are output as differential signals Pout+ and Pout−. The amplification device of this variation amplifies the differential signals Pin+ and Pin− and outputs the differential signals Pout+ and Pout-.

In the variation illustrated in FIG. 2C, the first transformer 41 is a balun transformer that converts a single-ended signal into differential signals, and the second transformer 42 is a differential transformer. The amplification device of this variation amplifies a single-ended signal Pin and outputs differential signals Pout+ and Pout−.

In any of the variations illustrated in FIGS. 2A, 2B, and 2C, the two wires of the differential wire pair 35 on the input side of the first differential amplifier circuit 31 intersect with each other, but the two wires of the differential wire pair 36 on the output side do not intersect with each other. Therefore, similarly to the first embodiment (FIG. 1A), these variations provide an advantageous effect of suppressing oscillation under a certain condition.

### Second Embodiment

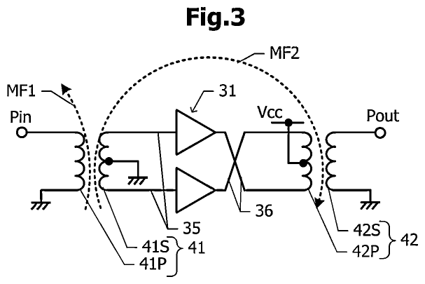

Next, an amplification device according to a second embodiment is described with reference to FIG. 3. Below, descriptions of components that are the same as those of the amplification device of the first embodiment (FIG. 1A) are omitted.

FIG. 3 is an equivalent circuit diagram of the amplification device according to the second embodiment. In the first embodiment (FIG. 1A), the two wires of the differential wire pair 35 on the input side of the first differential amplifier circuit 31 intersect with each other, and the two wires of the differential wire pair 36 on the output side do not intersect with each other. On the contrary, in the second embodiment, the two wires of the differential wire pair 36 on the output side of the first differential amplifier circuit 31 intersect with each other, and the two wires of the differential wire pair 35 on the input side do not intersect with each other.

Next, an advantageous effect of the second embodiment is described.

In the second embodiment, because the two wires of the differential wire pair 36 on the output side of the first differential amplifier circuit 31 intersect with each other, the phase of the electric current flowing through the second transformer 42 is reversed. As a result, the phase of the magnetic flux MF2 is also reversed. Therefore, similarly to the first embodiment (FIG. 1A), the second embodiment provides an advantageous effect of suppressing oscillation under a certain condition.

### Third Embodiment

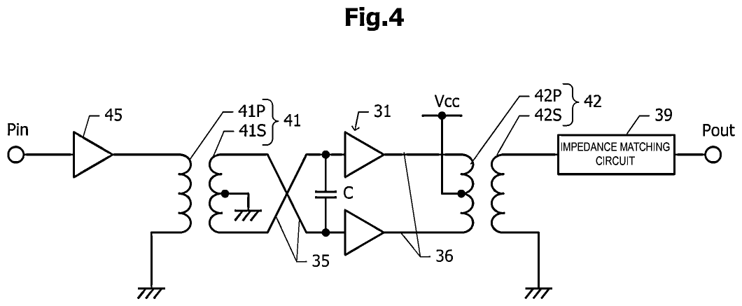

Next, an amplification device according to a third embodiment is described with reference to FIGS. 4 to 6. Below, descriptions of components that are the same as those of the amplification device of the first embodiment (FIG. 1A) are omitted.

FIG. 4 is an equivalent circuit diagram of the amplification device according to the third embodiment. The equivalent circuit including the first transformer 41, the differential wire pair 35, the first differential amplifier circuit 31, the differential wire pair 36, and the second transformer 42 is the same as the equivalent circuit of the amplification device according to the first embodiment. One end of the primary coil 41P of the first transformer 41 is connected to an output node of a single-ended amplifier circuit 45, and the other end of the primary coil 41P is grounded. A capacitor C is connected between a pair of differential input nodes of the first differential amplifier circuit 31. One end of the secondary coil 42S of the second transformer 42 is connected to the output terminal via an impedance matching circuit 39, and the other end of the secondary coil 42S is grounded.

A single-ended signal Pin is amplified by the single-ended amplifier circuit 45 and input to the primary coil 41P. The single-ended signal is converted into differential signals and impedance-matched by the first transformer 41, and the differential signals are input to the first differential amplifier circuit 31. Differential signals output from the first differential amplifier circuit 31 are converted into a single-ended signal by the second transformer 42. The single-ended signal obtained by the second transformer 42 is output as a single-ended signal Pout via the impedance matching circuit 39. The capacitor C is provided to stabilize high frequency operations.

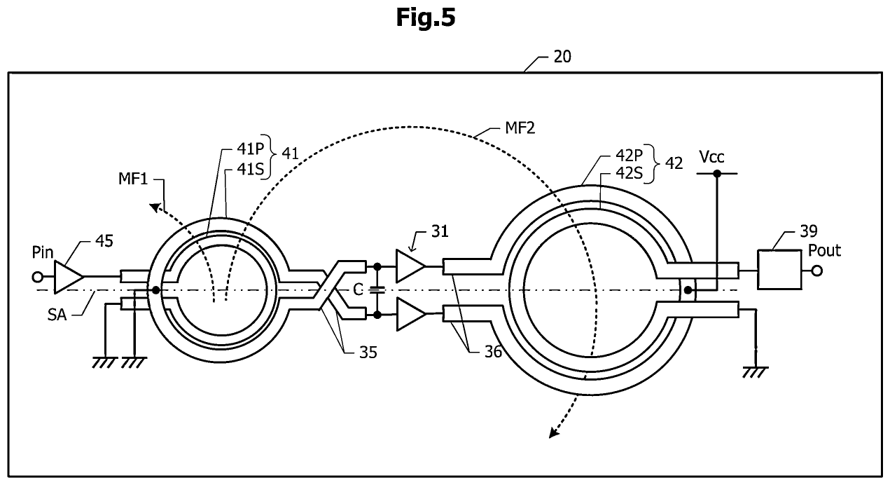

FIG. 5 is a schematic diagram illustrating the amplification device of the third embodiment with a focus on the planar shapes and the positional relationship of the first transformer 41 and the second transformer 42. The single-ended amplifier circuit 45, the first transformer 41, the first differential amplifier circuit 31, the second transformer 42, and the impedance matching circuit 39 are disposed in or on a substrate 20 formed of a semiconductor. The first transformer 41 and the second transformer 42 are implemented by conductor patterns in a multi-layer wiring layer disposed on the substrate 20.

The primary coil 41P and the secondary coil 41S of the first transformer 41 are concentrically arranged, and the primary coil 42P and the secondary coil 42S of the second transformer 42 are concentrically arranged. The number of turns of each of the primary coil 41P and the secondary coil 41S of the first transformer 41 and the primary coil 42P and the secondary coil 42S of the second transformer 42 is approximately one.

Ends of the secondary coil 41S and ends of the primary coil 41P of the first transformer 41 are disposed on the opposite sides of the center of the concentric circle. Similarly, ends of the secondary coil 42S and ends of the primary coil 42P of the second transformer 42 are disposed on the opposite sides of the center of the concentric circle. In plan view, the shape of each of the primary coil 41P and the secondary coil 41S of the first transformer 41 is line-symmetric with respect to a symmetry axis SA that passes through the center of the first transformer 41 and the center of the second transformer 42. Similarly, the shape of each of the primary coil 42P and the secondary coil 42S of the second transformer 42 is also line-symmetric with respect to the symmetry axis SA.

The pair of differential input nodes of the first differential amplifier circuit 31 are disposed in line-symmetric positions with respect to the symmetry axis SA. Similarly, the pair of differential output nodes of the first differential amplifier circuit 31 are also disposed in line-symmetric positions with respect to the symmetry axis SA. The two wires of the differential wire pair 35 connecting the secondary coil 41S of the first transformer 41 to the first differential amplifier circuit 31 intersect with each other in plan view of the substrate 20. The two wires of the differential wire pair 36 connecting the first differential amplifier circuit 31 to the primary coil 42P of the second transformer 42 do not intersect with each other.

The magnetic flux MF2 generated by the electric current flowing through the second transformer 42 is interlinked with the first transformer 41. At the position where the magnetic flux MF2 is interlinked with the first transformer 41, the magnetic flux MF2 is in phase with the magnetic flux MF1. In this case, the direction of an induction current flowing through the first transformer 41 as a result of a change in the magnetic flux MF2 becomes the opposite of the direction of the original electric current flowing through the first transformer 41. Accordingly, the induction current acts in a direction to weaken the original electric current.

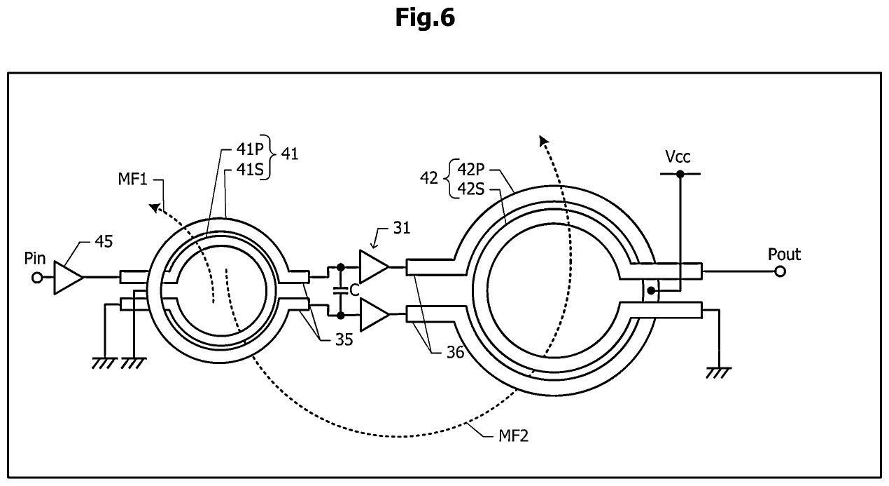

FIG. 6 is a schematic diagram illustrating the amplification device according to the comparative example with a focus on the planar shapes and the positional relationship of the first transformer 41 and the second transformer 42. In the comparative example, the two wires of the differential wire pair 35 connecting the first transformer 41 to the first differential amplifier circuit 31 do not intersect with each other. With this configuration, at the position where the magnetic flux MF2 is interlinked with the first transformer 41, the magnetic flux MF2 is in reverse phase with the magnetic flux MF1. In this case, the direction of an induction current flowing through the first transformer 41 as a result of a change in the magnetic flux MF2 becomes the same as the direction of an electric current flowing through the first transformer 41, and the induction current acts in a direction to strengthen the original electric current. As a result, a positive feedback is applied from the output side to the input side of the first differential amplifier circuit 31. This increases the chance of the occurrence of parasitic oscillation.

In contrast, in the third embodiment, an induction current flowing through the first transformer 41 as a result of a change in the magnetic flux MF2 acts in a direction to weaken the original electric current flowing through the first transformer 41. As a result, a negative feedback is applied from the output side to the input side of the first differential amplifier circuit 31. This provides an advantageous effect of reducing the chance of the occurrence of parasitic oscillation. Thus, when a condition causing a positive feedback is satisfied in a state in which the two wires of the differential wire pair 35 are arranged so as not to intersect with each other, it is possible to suppress parasitic oscillation by arranging the two wires of the differential wire pair 35 to intersect with each other so that a negative feedback is applied.

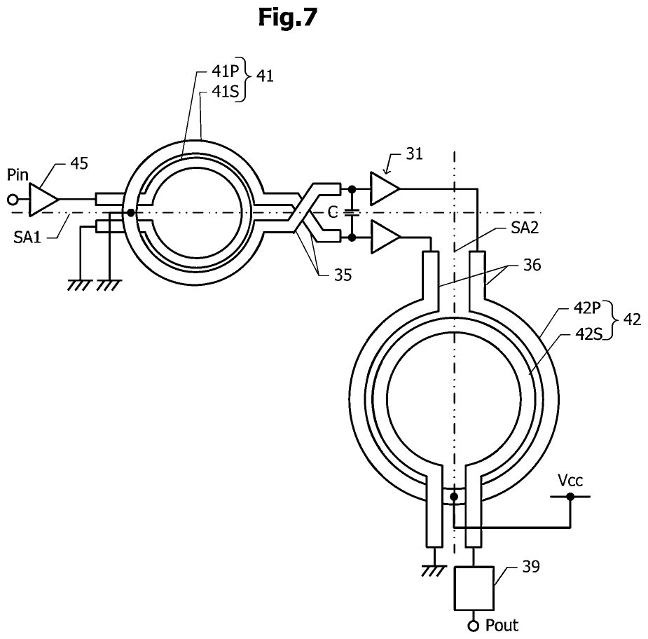

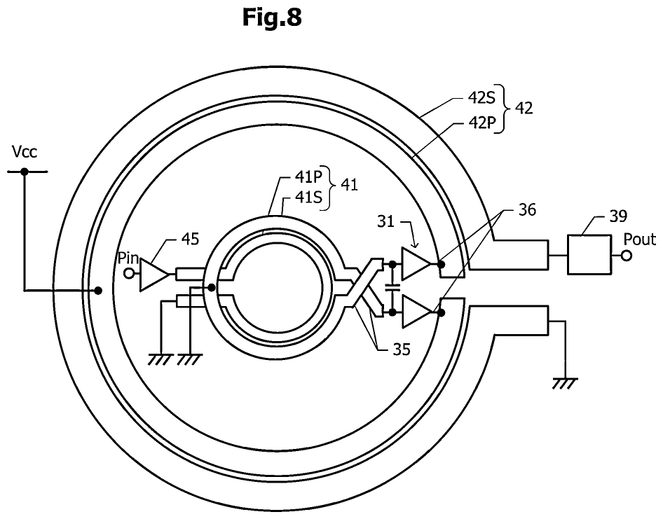

Next, with reference to FIGS. 7 and 8, amplification devices according to variations of the third embodiment are described.

FIG. 7 is a schematic diagram illustrating an amplification device according to a variation of the third embodiment with a focus on the planar shapes and the positional relationship of the first transformer 41 and the second transformer 42. In the third embodiment (FIG. 5), the first transformer 41 and the second transformer 42 have the same symmetry axis SA. On the other hand, in this variation, a symmetry axis SA1 of the first transformer 41 and a symmetry axis SA2 of the second transformer 42 intersect with each other at a certain angle. For example, the symmetry axis SA1 and the symmetry axis SA2 are orthogonal to each other.

Both of the pair of differential input nodes and the pair of differential output nodes of the first differential amplifier circuit 31 are arranged line-symmetrically with respect to the symmetry axis SA1. Alternatively, both of the pair of differential input nodes and the pair of differential output nodes of the first differential amplifier circuit 31 may be arranged line-symmetrically with respect to the symmetry axis SA2.

FIG. 8 is a schematic diagram illustrating an amplification device according to another variation of the third embodiment with a focus on the planar shapes and the positional relationship of the first transformer 41 and the second transformer 42. In the third embodiment (FIG. 5), the first transformer 41 and the second transformer 42 are arranged side by side in the plane of the substrate 20. On the other hand, in this variation, the first transformer 41 is enclosed in the second transformer 42 in plan view.

Also in the variations illustrated in FIGS. 7 and 8, as a result of magnetic coupling between the second transformer 42 and the first transformer 41, a positive feedback or a negative feedback is applied from the output side to the input side of the first differential amplifier circuit 31. When a condition causing a positive feedback is satisfied by a configuration in which the two wires of the differential wire pair 35 do not intersect with each other, it is possible to apply a negative feedback by arranging the two wires of the differential wire pair 35 to intersect with each other. This makes it possible to suppress parasitic oscillation resulting from a feedback.

### Fourth Embodiment

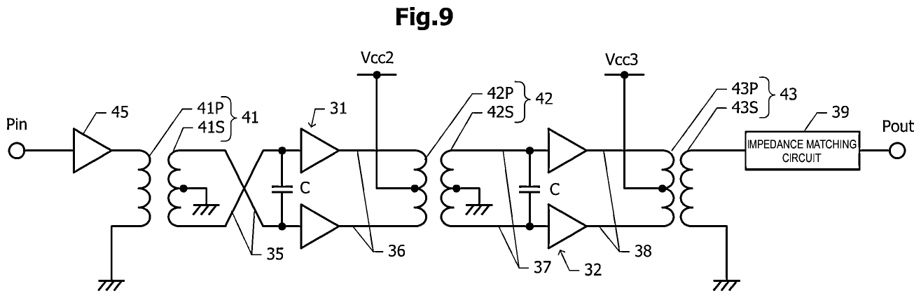

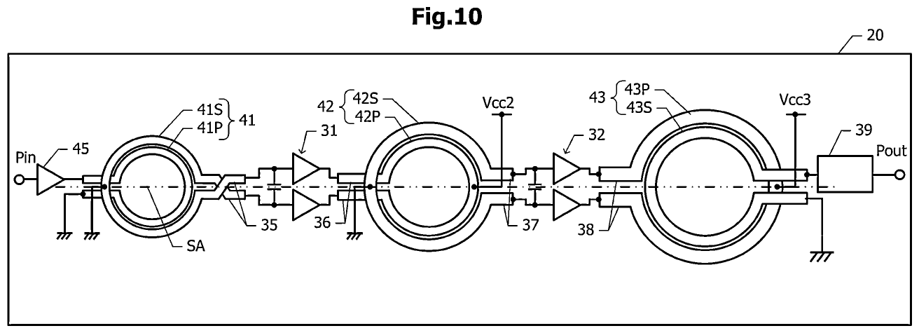

Next, an amplification device according to a fourth embodiment is described with reference to FIGS. 9 and 10. Below, descriptions of components that are the same as those of the amplification device of the third embodiment (FIGS. 4 and 5) are omitted.

FIG. 9 is an equivalent circuit diagram of the amplification device according to the fourth embodiment. The amplification device of the third embodiment (FIG. 4) has a two-stage configuration including the single-ended amplifier circuit 45 and the first differential amplifier circuit 31. On the other hand, the amplification device of the fourth embodiment has a three-stage configuration in which a downstream differential amplifier circuit 32 is provided downstream of the first differential amplifier circuit 31.

In the third embodiment (FIG. 4), a balun transformer is used as the second transformer 42. In contrast, in the fourth embodiment, a differential transformer is used as the second transformer 42. An intermediate point of the secondary coil 42S of the second transformer 42 is grounded. Ends of the secondary coil 42S of the second transformer 42 are connected to a pair of differential input nodes of the downstream differential amplifier circuit 32. Similarly to the first differential amplifier circuit 31, a capacitor C is connected between the pair of differential input nodes of the downstream differential amplifier circuit 32. Differential signals output from the first differential amplifier circuit 31 are impedance-matched by the second transformer 42 and input to the downstream differential amplifier circuit 32.

A downstream transformer 43 is connected to the output side of the downstream differential amplifier circuit 32. The downstream transformer 43 is a balun transformer that converts differential signals into a single-ended signal. An intermediate point of a primary coil 43P of the downstream transformer 43 is connected to a power supply voltage Vcc3. One end of a secondary coil 43S of the downstream transformer 43 is grounded, and the other end of the secondary coil 43S is connected to an output terminal via the impedance matching circuit 39. Differential signals output from the downstream differential amplifier circuit 32 are converted into a single-ended signal by the downstream transformer 43, and the single-ended signal is output as the single-ended signal Pout via the impedance matching circuit 39.

FIG. 10 is a schematic diagram illustrating the amplification device according to the fourth embodiment with a focus on the planar shapes and the positional relationship of the first transformer 41, the second transformer 42, and the downstream transformer 43. The single-ended amplifier circuit 45, the first transformer 41, the first differential amplifier circuit 31, the second transformer 42, the downstream differential amplifier circuit 32, the downstream transformer 43, and the impedance matching circuit 39 are disposed in or on the substrate 20 formed of a semiconductor. The first transformer 41, the second transformer 42, and the downstream transformer 43 are implemented by conductor patterns in a multi-layer wiring layer disposed on the substrate 20.

In the third embodiment (FIG. 5), one end of the secondary coil 42S of the second transformer 42 is grounded, and the other end of the secondary coil 42S is connected to the impedance matching circuit 39. In contrast, in the fourth embodiment, an intermediate point of the secondary coil 42S of the second transformer 42 is grounded, and ends of the secondary coil 42S are connected to a pair of differential input nodes of the downstream differential amplifier circuit 32 via a differential wire pair 37.

The primary coil 43P and the secondary coil 43S of the downstream transformer 43 are arranged concentrically, and the number of turns of each of the primary coil 43P and the secondary coil 43S is approximately one. The center of the downstream transformer 43 is located on the symmetry axis SA passing through the center of the first transformer 41 and the center of the second transformer 42. In plan view, the shape of each of the primary coil 43P and the secondary coil 43S of the downstream transformer 43 is line-symmetric with respect to the symmetry axis SA. The pair of differential input nodes of the downstream differential amplifier circuit 32 are arranged line-symmetrically with respect to the symmetry axis SA, and the pair of differential output nodes are also arranged line-symmetrically with respect to the symmetry axis SA.

The pair of differential output nodes of the downstream differential amplifier circuit 32 are connected to the ends of the primary coil 43P of the downstream transformer 43 via a differential wire pair 38. An intermediate point of the primary coil 43P is connected to a power supply voltage Vcc3. One end of the secondary coil 43S of the downstream transformer 43 is grounded, and the other end of the secondary coil 43S is connected to the output terminal via the impedance matching circuit 39.

The two wires of the differential wire pair 35, which connect the secondary coil 41S of the first transformer 41 to the first differential amplifier circuit 31, intersect with each other in plan view. The two wires of each of the differential wire pair 36 connecting the first differential amplifier circuit 31 to the primary coil 42P of the second transformer 42, the differential wire pair 37 connecting the secondary coil 42S of the second transformer 42 to the downstream differential amplifier circuit 32, and the differential wire pair 38 connecting the downstream differential amplifier circuit 32 to the primary coil 43P of the downstream transformer 43 do not intersect with each other.

Next, an advantageous effect of the fourth embodiment is described.

Similarly to the third embodiment, the fourth embodiment can also suppress parasitic oscillation resulting from a feedback from the output side to the input side of the first differential amplifier circuit 31. Also, when a condition causing a positive feedback from the output side of the downstream differential amplifier circuit 32 to the input side of the first differential amplifier circuit 31 is satisfied by a configuration in which the two wires of the differential wire pair 35 do not intersect with each other, it is possible to suppress parasitic oscillation resulting from a feedback from the output side of the downstream differential amplifier circuit 32 to the input side of the first differential amplifier circuit 31 by arranging the two wires of the differential wire pair 35 to intersect with each other.

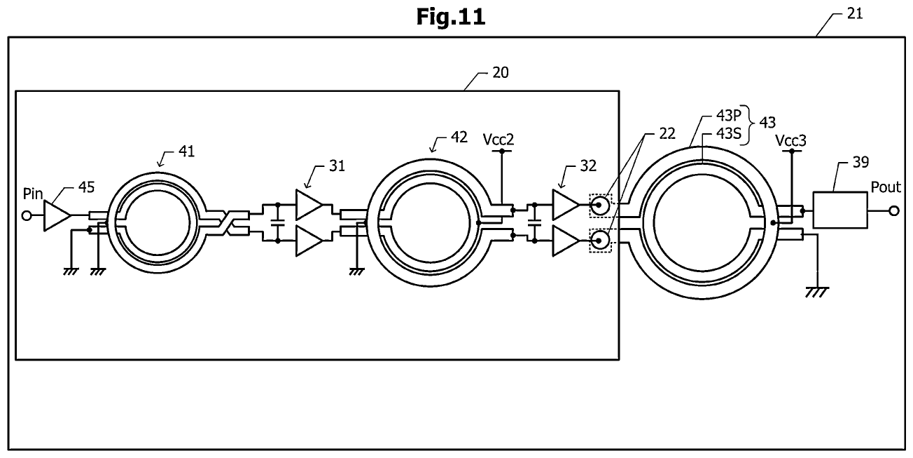

Next, a variation of the fourth embodiment is described with reference to FIG. 11.

FIG. 11 is a schematic diagram illustrating an amplification device according to a variation of the fourth embodiment with a focus on the planar shapes and the positional relationship of the first transformer 41, the second transformer 42, and the downstream transformer 43. In the fourth embodiment (FIG. 10), the single-ended amplifier circuit 45, the first transformer 41, the first differential amplifier circuit 31, the second transformer 42, the downstream differential amplifier circuit 32, the downstream transformer 43, and the impedance matching circuit 39 are all disposed in or on the substrate 20 formed of a semiconductor. In contrast, in the variation illustrated in FIG. 11, the single-ended amplifier circuit 45, the first transformer 41, the first differential amplifier circuit 31, the second transformer 42, and the downstream differential amplifier circuit 32 are disposed in or on the substrate 20, and the substrate 20 is mounted on a module substrate 21.

The downstream transformer 43 and the impedance matching circuit 39 are disposed in or on the module substrate 21. The module substrate 21 has a multilayer structure, and the downstream transformer 43 is implemented by a conductor pattern in the module substrate 21. The pair of differential output nodes of the downstream differential amplifier circuit 32 are connected to the ends of the primary coil 43P of the downstream transformer 43 via bumps 22. The positional relationship among the first transformer 41, the second transformer 42, and the downstream transformer 43 in plan view is substantially the same as the positional relationship among these components in the fourth embodiment (FIG. 10).

As in this variation, the downstream transformer 43 may be disposed in or on the module substrate 21. More generally, at least one of the first transformer 41, the second transformer 42, and the downstream transformer 43 may be disposed in or on the module substrate 21.

Next, another variation of the fourth embodiment is described. In the fourth embodiment, the two wires of the differential wire pair 35 connecting the first transformer 41 to the first differential amplifier circuit 31 intersect with each other. As another configuration, as in the amplification device of the second embodiment (FIG. 3), the two wires of the differential wire pair 36 connecting the first differential amplifier circuit 31 to the second transformer 42 may be arranged to intersect with each other, and the two wires of the differential wire pair 35 may be arranged to not intersect with each other.

### Fifth Embodiment

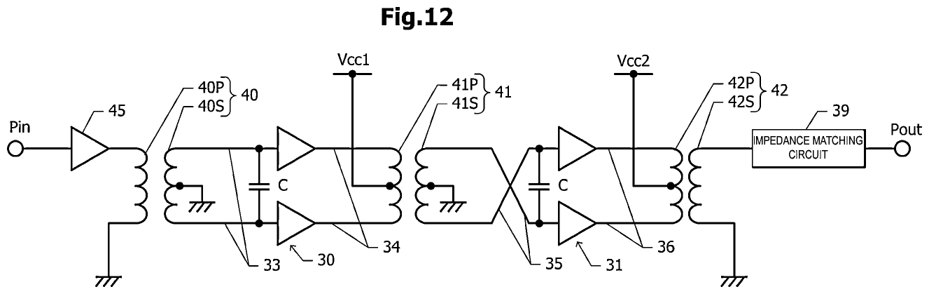

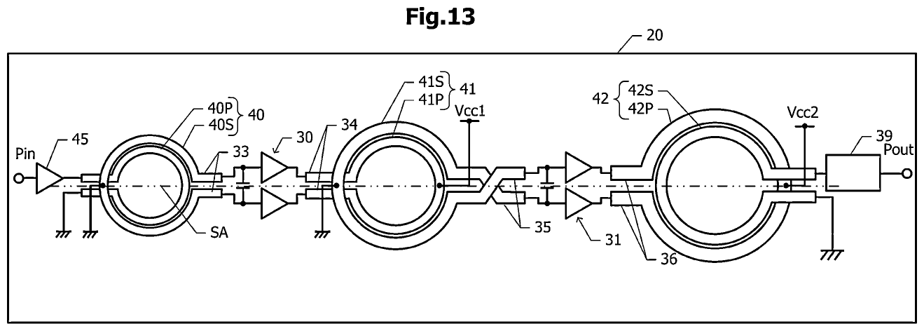

Next, an amplification device according to a fifth embodiment is described with reference to FIGS. 12 and 13. Below, descriptions of components that are the same as those of the amplification device of the fourth embodiment (FIGS. 9 and 10) are omitted.

FIG. 12 is an equivalent circuit diagram of the amplification device according to the fifth embodiment. In the fourth embodiment (FIGS. 9 and 10), the amplification device has a three-stage configuration in which the single-ended amplifier circuit 45, the first differential amplifier circuit 31, and the downstream differential amplifier circuit 32 are arranged in this order. On the other hand, in the fifth embodiment, the amplification device has a three-stage configuration in which the single-ended amplifier circuit 45, an upstream differential amplifier circuit 30, and the first differential amplifier circuit 31 are arranged in this order. Similarly to the fourth embodiment, the two wires of the differential wire pair 35 on the input side of the first differential amplifier circuit 31 intersect with each other.

An upstream transformer 40 is inserted between the single-ended amplifier circuit 45 and the upstream differential amplifier circuit 30. The output node of the single-ended amplifier circuit 45 is connected to one end of a primary coil 40P of the upstream transformer 40, and the other end of the primary coil 40P is grounded. Ends of a secondary coil 40S of the upstream transformer 40 are connected to a pair of differential input nodes of the upstream differential amplifier circuit 30 via a differential wire pair 33. An intermediate point of the secondary coil 40S of the upstream transformer 40 is grounded. A capacitor C is connected between the pair of differential input nodes of the upstream differential amplifier circuit 30.

A pair of differential output nodes of the upstream differential amplifier circuit 30 are connected to the ends of the primary coil 41P of the first transformer 41 via a differential wire pair 34. An intermediate point of the primary coil 41P is connected to a power supply voltage Vcc1. The circuit configuration from the secondary coil 41S of the first transformer 41 to the primary coil 42P of the second transformer 42 is the same as the circuit configuration from the secondary coil 41S of the first transformer 41 to the primary coil 42P of the second transformer 42 of the amplification device according to the fourth embodiment (FIG. 9).

The second transformer 42 is a balun transformer that converts differential signals into a single-ended signal. One end of the secondary coil 42S of the second transformer 42 is connected to the output terminal via the impedance matching circuit 39, and the other end of the secondary coil 42S is grounded.

FIG. 13 is a schematic diagram illustrating the amplification device according to the fifth embodiment with a focus on the planar shapes and the positional relationship of the upstream transformer 40, the first transformer 41, and the second transformer 42. Similarly to the first transformer 41 of the amplification device according to the fourth embodiment (FIG. 10), the upstream transformer 40 includes the primary coil 40P and the secondary coil 40S that are arranged concentrically. In plan view, the shape of each of the primary coil 40P and the secondary coil 40S is line-symmetric with respect to the symmetry axis SA.

The two wires of each of the differential wire pair 33 connecting the secondary coil 40S of the upstream transformer 40 to the upstream differential amplifier circuit 30 and the differential wire pair 34 connecting the upstream differential amplifier circuit 30 to the primary coil 41P of the first transformer 41 do not intersect with each other.

Next, an advantageous effect of the fifth embodiment is described.

When a condition causing a positive feedback from the output side to the input side of the first differential amplifier circuit 31 is satisfied and a condition causing a positive feedback from the output side of the first differential amplifier circuit 31 to the input side of the upstream differential amplifier circuit 30 are satisfied by a configuration in which the two wires of the differential wire pair 35 do not intersect with each other, it is possible to achieve an advantageous effect of suppressing parasitic oscillation resulting from a feedback by arranging the two wires of the differential wire pair 35 to intersect with each other.

### Sixth Embodiment

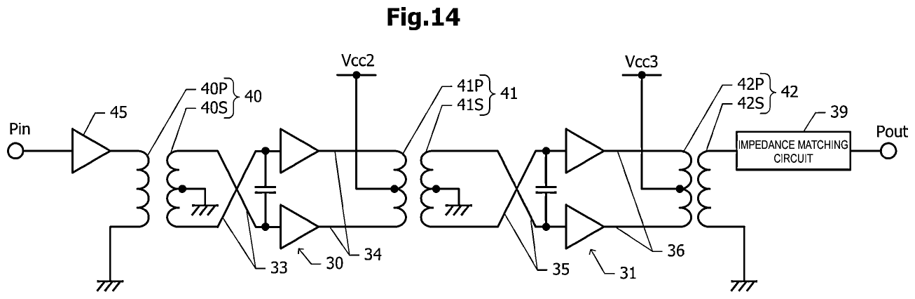

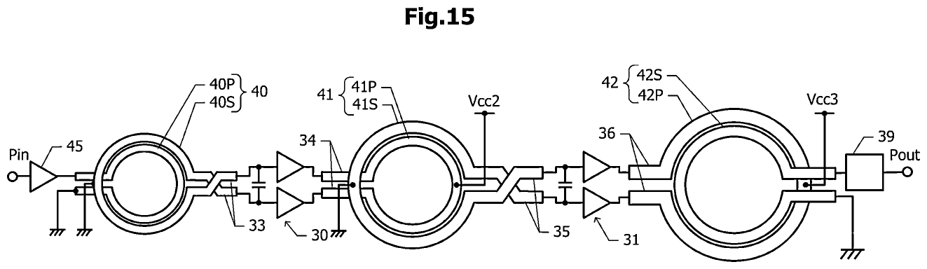

Next, an amplification device according to a sixth embodiment is described with reference to FIGS. 14 and 15. Below, descriptions of components that are the same as those of the amplification device of the fifth embodiment (FIGS. 12 and 13) are omitted.

FIG. 14 is an equivalent circuit diagram of the amplification device according to the sixth embodiment. FIG. 15 is a schematic diagram illustrating the amplification device according to the sixth embodiment with a focus on the planar shapes and the positional relationship of the upstream transformer 40, the first transformer 41, and the second transformer 42. In the fifth embodiment (FIGS. 12 and 13), although the two wires of the differential wire pair 35 on the input side of the first differential amplifier circuit 31 intersect with each other, the two wires of each of the differential wire pair 33 on the input side of the upstream differential amplifier circuit 30 and the differential wire pair 34 on the output side of the upstream differential amplifier circuit 30 do not intersect with each other. In contrast, in the sixth embodiment, the two wires of the differential wire pair 35 intersect with each, and the two wires of the differential wire pair 33 connecting the secondary coil 40S of the upstream transformer 40 to the upstream differential amplifier circuit 30 also intersect with each other.

Next, an advantageous effect of the sixth embodiment is described.

In the sixth embodiment, when a condition causing a positive feedback from the output side to the input side of the upstream differential amplifier circuit 30 is satisfied by a configuration in which the two wires of the differential wire pair 33 do not intersect with each other, because the two wires of the differential wire pair 33 are arranged to intersect with each other, it is possible to achieve an advantageous effect of suppressing parasitic oscillation resulting from a feedback from the output side to the input side of the upstream differential amplifier circuit 30.

Next, a variation of the sixth embodiment is described. In the sixth embodiment, the two wires of the differential wire pair 33 on the input side of the upstream differential amplifier circuit 30 are arranged to intersect with each other. However, instead of the differential wire pair 33, the two wires of the differential wire pair 34 on the output side of the upstream differential amplifier circuit 30 may be arranged to intersect with each other.

### Seventh Embodiment

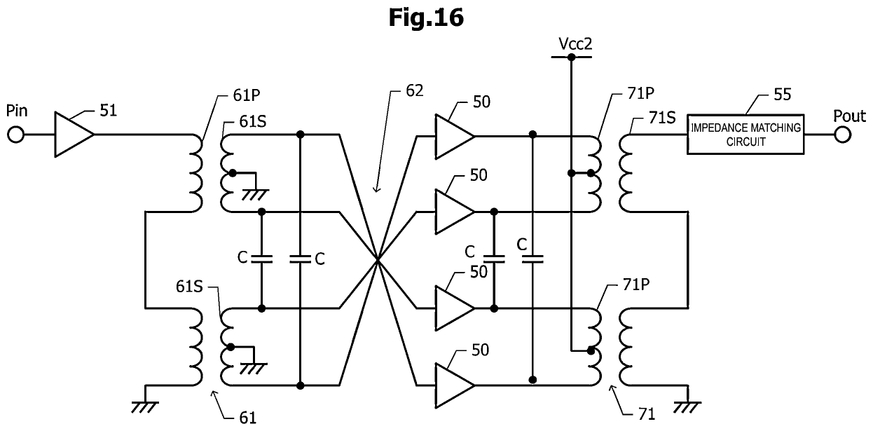

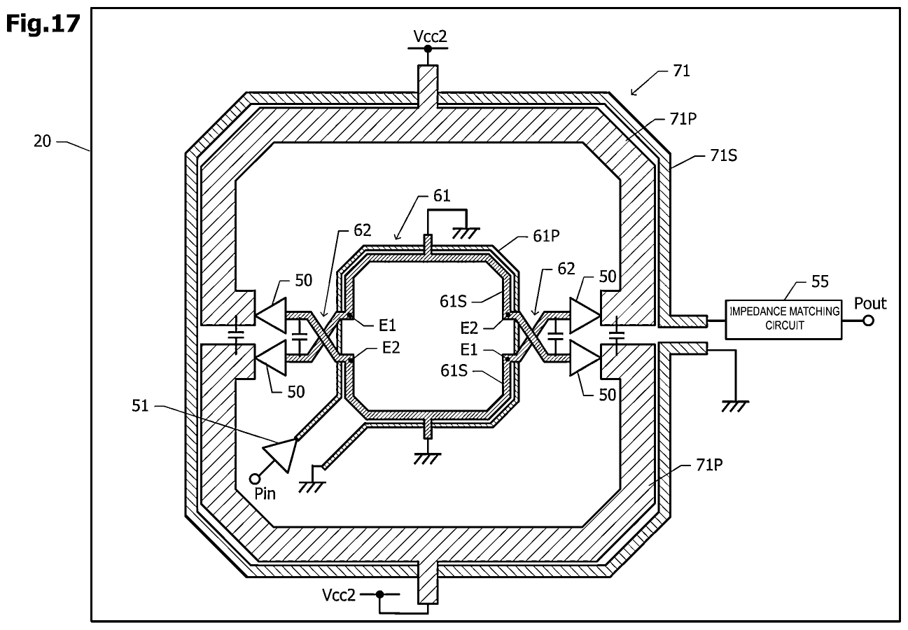

Next, an amplification device according to a seventh embodiment is described with reference to FIGS. 16 and 17. Below, descriptions of components that are the same as those of the amplification device of the third embodiment (FIGS. 4 and 5) are omitted.

FIG. 16 is an equivalent circuit diagram of the amplification device according to the seventh embodiment. The amplification device according to the seventh embodiment includes a single-ended amplifier circuit 51, a power distribution circuit 61, four amplifier circuits 50, a power combining circuit 71, and an impedance matching circuit 55. Each of the four amplifier circuits 50 has one input node and one output node. The four amplifier circuits 50 function as two differential amplifier circuits each of which is implemented by two of the four amplifier circuits 50.

The power distribution circuit 61 includes one input wire 61P and two output wires 61S. An intermediate point of each of the two output wires 61S is grounded. Each of the two output wires 61S is magnetically coupled to the one input wire 61P. One end of the input wire 61P is connected to the output node of the single-ended amplifier circuit 51, and the other end of the input wire 61P is grounded. When a single-ended signal Pin is input to the single-ended amplifier circuit 51, the single-ended signal amplified by the single-ended amplifier circuit 51 is input to the input wire 61P of the power distribution circuit 61.

The power distribution circuit 61 converts the single-ended signal input from the single-ended amplifier circuit 51 into two pairs of differential signals and outputs the two pairs of differential signals from the two output wires 61S. Ends of one of the two output wires 61S are connected to the two input nodes of one of the two differential amplifier circuits implemented by the four amplifier circuits 50, and ends of the other one of the two output wires 61S are connected to the two input nodes of the other one of the two differential amplifier circuits. Here, two wires connecting the ends of each of the output wires 61S of the power distribution circuit 61 to the input nodes of two amplifier circuits 50 are referred to as a cross wire pair 62. A specific configuration of the cross wire pair 62 is described later with reference to FIG. 17.

The power combining circuit 71 includes two input wires 71P and one output wire 71S. Each of the two input wires 71P is magnetically coupled to the one output wire 71S. The power combining circuit 71 combines multiple differential signals into one single-ended signal. Two output nodes of one of two differential amplifier circuits implemented by the four amplifier circuits 50 are connected to the ends of one of the two input wires 71P, and two output nodes of the other one of the two differential amplifier circuits are connected to the ends of the other one of the two input wires 71P. Two pairs of differential signals output from the two differential amplifier circuits are input to the two input wires 71P.

An intermediate point of each of the two input wires 71P is connected to a power supply voltage Vcc2. Power is supplied from the power supply voltage Vcc2 to the amplifier circuits 50 via the input wires 71P.

The power combining circuit 71 combines differential signals input to the two input wires 71P into one single-ended signal and outputs the single-ended signal from the output wire 71S. One end of the output wire 71S is grounded, and the other end is connected to the output terminal via the impedance matching circuit 55. The single-ended signal obtained by the power combining circuit 71 is output from the output terminal as a single-ended signal Pout.

In addition to the function to divide one single-ended signal into two pairs of differential signals, the power distribution circuit 61 has an impedance conversion function for achieving impedance matching. Similarly, in addition to the function for combining electric power, the power combining circuit 71 has an impedance conversion function for achieving impedance matching.

A capacitor C is connected between the positive phase output end of one of the output wires 61S of the power distribution circuit 61 and the negative phase output end of the other one of the output wires 61S. Also, a capacitor C is connected between the negative phase output end of the one of the output wires 61S and the positive phase output end of the other one of the output wires 61S. A capacitor C is connected between the positive phase output node of one of the two differential amplifier circuits and the negative phase output node of the other one of the two differential amplifier circuits. Also, a capacitor C is connected between the negative phase output node of the one of the two differential amplifier circuits and the positive phase output node of the other one of the two differential amplifier circuits. The capacitors C are provided to stabilize high frequency operations.

FIG. 17 is a schematic diagram illustrating the amplification device according to the seventh embodiment with a focus on the planar shapes and the positional relationship of the power distribution circuit 61 and the power combining circuit 71. The single-ended amplifier circuit 51, the power distribution circuit 61, the four amplifier circuits 50, the power combining circuit 71, and the impedance matching circuit 55 are disposed in or on the substrate 20 formed of a semiconductor. In FIG. 17, the input wire 61P and the output wires 61S of the power distribution circuit 61 and the input wires 71P and the output wire 71S of the power combining circuit 71 are hatched.

The input wire 61P of the power distribution circuit 61 is laid out along an annular shape. For example, the input wire 61P is laid out along the perimeter of a square the triangular corners of which are cut off. The input wire 61P may also be laid out along the perimeter of any other annular shape, such as a circle or a regular polygon. The number of turns of the input wire 61P is approximately one. The two output wires 61S of the power distribution circuit 61 are laid out along the input wire 61P with an annular shape at a position slightly inside of the input wire 61P. The length of each of the two output wires 61S is approximately one half of the length of the input wire 61P. An intermediate point of each of the two output wires 61S is grounded.

The upstream end and the downstream end of each of the two output wires 61S in a direction (for example, a clockwise direction) in which the output wires 61S go around the annular shape are referred to as a first end E1 and a second end E2, respectively. Two first ends E1 and two second ends E2 are arranged alternately in the circumferential direction. One of the first end E1 and the second end E2 functions as a positive phase output end, and the other one of the first end E1 and the second end E2 functions as a negative phase output end.

The four amplifier circuits 50 are arranged along the circumferential direction of the annular shape. More specifically, the input nodes of the amplifier circuits 50 are disposed in the same positions as the two first ends E1 and the two second ends E2 in the circumferential direction and are disposed in positions that are slightly outside of the first ends E1 and the second ends E2 in the radial direction. Of the two first ends E1 and the two second ends E2, each pair of the first end E1 and the second end E2 closest to each other in the circumferential direction are connected via the two wires of one of the cross wire pairs 62 to the two input nodes of the two amplifier circuits 50 that are adjacent to each other in the circumferential direction. The two wires of each of the multiple cross wire pairs 62 intersect with each other in plan view.

Two amplifier circuits 50 connected to one of the output wires 61S of the power distribution circuit 61 function as one differential amplifier circuit, and two amplifier circuits 50 connected to the other one of the output wires 61S function as another differential amplifier circuit.

The output wire 71S of the power combining circuit 71 is laid out along an annular shape to surround the power distribution circuit 61 in plan view. The number of turns of the output wire 71S is approximately one. One end of the output wire 71S is grounded, and the other end is connected to the impedance matching circuit 55.

The two input wires 71P are laid out along the output wire 71S, which is laid out along the annular shape, at positions slightly inside of the output wire 71S. The length of each of the two input wires 71P is approximately one half of the length of the output wire 71S. Each of the input wires 71P extends from the output node of one amplifier circuit 50, goes around approximately one half of the circumference, and reaches the output node of another amplifier circuit 50. An intermediate point of each of the input wires 71P is connected to the power supply voltage Vcc2.

Next, an advantageous effect of the seventh embodiment is described.

When the power distribution circuit 61 and the power combining circuit 71 are magnetically coupled to each other, a positive feedback or a negative feedback is applied from the output side to the input side of the amplifier circuits 50. When the two wires of each cross wire pair 62 are arranged to intersect with each other, the phase of an electric current flowing through the corresponding input wire 71P of the power combining circuit 71 is reversed. Accordingly, when a condition causing a positive feedback is satisfied by a configuration in which the two wires of each cross wire pair 62 do not intersect with each other, it is possible to apply a negative feedback by arranging the two wires to intersect with each other. Configuring the amplification device such that a negative feedback is applied from the output side to the input side of the amplifier circuits 50 makes it possible to achieve an advantageous effect of suppressing parasitic oscillation resulting from a feedback.

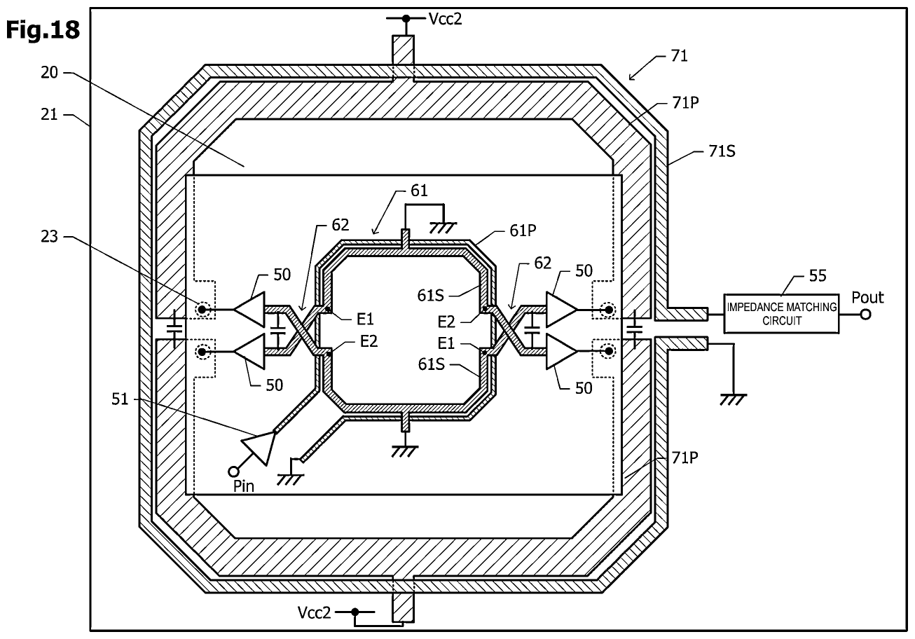

Next, a variation of the seventh embodiment is described with reference to FIG. 18.

FIG. 18 is a schematic diagram illustrating an amplification device according to a variation of the seventh embodiment with a focus on the planar shapes and the positional relationship of the power distribution circuit 61 and the power combining circuit 71. In the seventh embodiment (FIG. 17), the power combining circuit 71 is disposed in or on the substrate 20 formed of a semiconductor. In contrast, in the variation of the seventh embodiment illustrated in FIG. 18, the substrate 20 is mounted on a module substrate 21. The power combining circuit 71 is disposed in or on the module substrate 21.

The output node of each of the multiple amplifier circuits 50 is connected via a bump 23 to one of the ends of the two input wires 71P of the power combining circuit 71. The power distribution circuit 61 is disposed in or on the substrate 20 formed of a semiconductor. In a state in which the substrate 20 is mounted on the module substrate 21, the positional relationship in plan view between the power distribution circuit 61 and the power combining circuit 71 is the same as the positional relationship in the seventh embodiment (FIG. 17).

Similarly to the seventh embodiment, the configuration of this variation, in which the power combining circuit 71 is disposed in or on the module substrate 21, also has an advantageous effect of suppressing parasitic oscillation resulting from a feedback.

### Eighth Embodiment

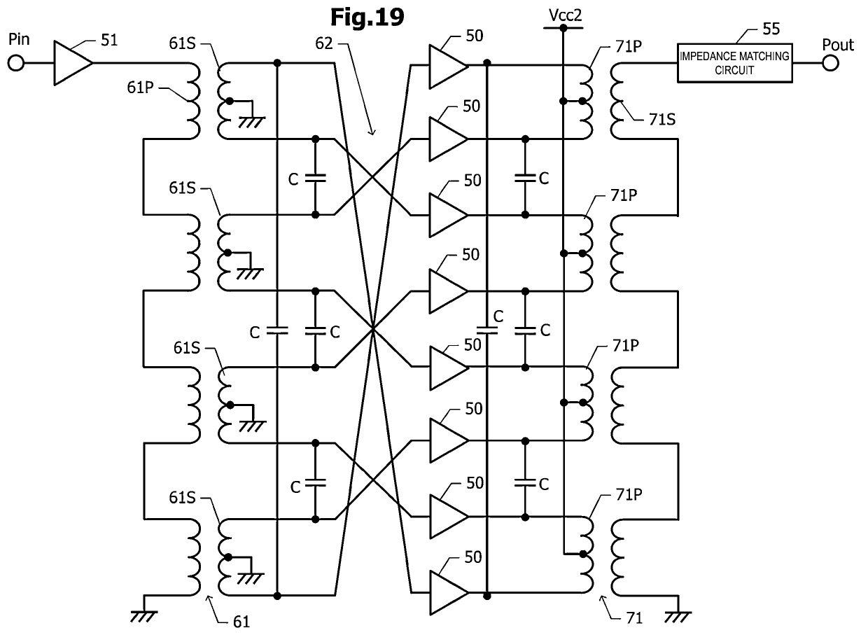

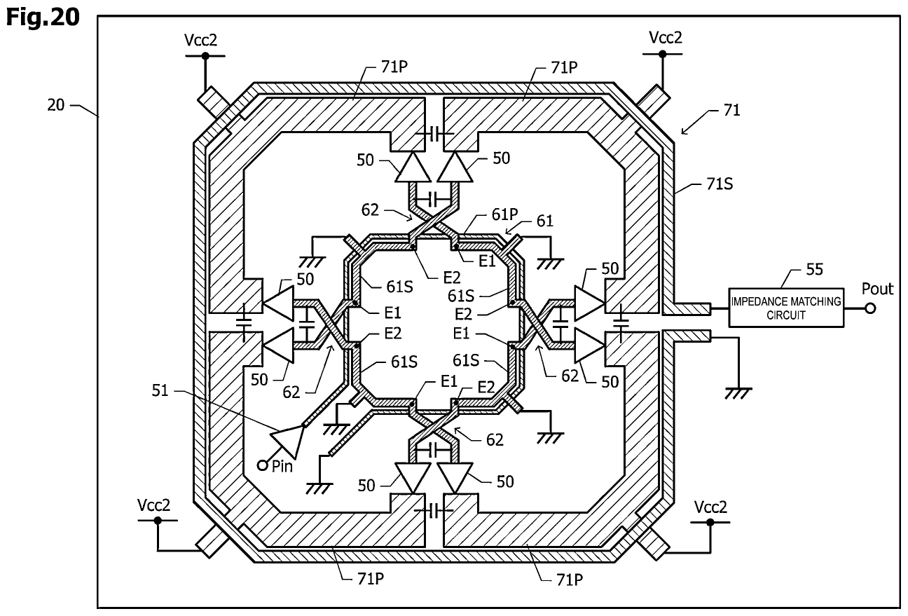

Next, an amplification device according to an eighth embodiment is described with reference to FIGS. 19 and 20. Below, descriptions of components that are the same as those of the amplification device of the seventh embodiment (FIGS. 16 and 17) are omitted.

FIG. 19 is an equivalent circuit diagram of the amplification device according to the eighth embodiment. The amplification device of the seventh embodiment (FIG. 16) includes four amplifier circuits 50. In contrast, the amplification device of the eighth embodiment includes eight amplifier circuits 50. Among the eight amplifier circuits 50, four amplifier circuits 50 function as a positive phase amplifier circuit, and the other four amplifier circuits 50 function as a negative phase amplifier circuit. That is, the eight amplifier circuits 50 function as a differential amplifier circuit including four positive phase input nodes, four negative phase input nodes, four positive phase output nodes, and four negative phase output nodes.

The power distribution circuit 61 includes one input wire 61P and four output wires 61S. The power distribution circuit 61 divides a single-ended signal input from the single-ended amplifier circuit 51 into four pairs of differential signals, and outputs each pair of differential signals from one of the four output wires 61S. An intermediate point of each of the four output wires 61S is grounded. One end and the other end of each of the four output wires 61S are connected to one positive phase input node and one negative phase input node of the differential amplifier circuit implemented by the eight amplifier circuits 50 via two wires of one of the cross wire pairs 62.

The power combining circuit 71 includes one output wire 71S and four input wires 71P. One end and the other end of each of the four input wires 71P are connected to one positive phase output node and one negative phase output node of the differential amplifier circuit implemented by the eight amplifier circuits 50. An intermediate point of each of the four input wires 71P is connected to the power supply voltage Vcc2. The combination of the positive phase output node and the negative phase output node connected to one of the four input wires 71P of the power combining circuit 71 is not necessarily the same as the combination of the positive phase input node and the negative phase input node connected to the corresponding one of the four output wires 61S of the power distribution circuit 61.

A capacitor C is connected between each pair of the positive phase output end of one of the output wires 61S and the negative phase output end of another one of the output wires 61S of the power distribution circuit 61. A capacitor C is connected between each pair of the positive phase input end of one of the input wires 71P and the negative phase input end of another one of the input wires 71P of the power combining circuit 71. The multiple capacitors C are provided to stabilize high frequency operations.

One end of the output wire 71S of the power combining circuit 71 is grounded, and the other end is connected to the impedance matching circuit 55. When a single-ended signal Pin is input to the single-ended amplifier circuit 51, an amplified single-ended signal Pout is output via the impedance matching circuit 55.

FIG. 20 is a schematic diagram illustrating the amplification device according to the eighth embodiment with a focus on the planar shapes and the positional relationship of the power distribution circuit 61 and the power combining circuit 71. The single-ended amplifier circuit 51, the power distribution circuit 61, the eight amplifier circuits 50, the power combining circuit 71, and the impedance matching circuit 55 are disposed in or on the substrate 20 formed of a semiconductor. In FIG. 20, the input wire 61P and the output wires 61S of the power distribution circuit 61 and the input wires 71P and the output wire 71S of the power combining circuit 71 are hatched.

The shapes and the positional relationship in plan view of the input wire 61P of the power distribution circuit 61 and the output wire 71S of the power combining circuit 71 are the same as those in the seventh embodiment (FIG. 17). In the seventh embodiment (FIG. 17), two output wires 61S are disposed slightly inside of the input wire 61P. In contrast, in the eighth embodiment, four output wires 61S are disposed slightly inside of the input wire 61P. The length of each of the four output wires 61S is approximately one fourth of the length of the input wire 61P. The four output wires 61S as a whole go around the circumference approximately once along the output wire 71S.

Similarly to the seventh embodiment (FIG. 17), one end of each of the output wires 61S is referred to as a first end E1, and the other end is referred to as a second end E2. Multiple first ends E1 and multiple second ends E2 are arranged alternately in the circumferential direction. One of the first end E1 and the second end E2 functions as a positive phase output end, and the other one of the first end E1 and the second end E2 functions as a negative phase output end.

Eight amplifier circuits 50 are arranged in the circumferential direction outside of the input wire 61P of the power distribution circuit 61. The input nodes of the eight amplifier circuits 50 are disposed in substantially the same positions as the first ends E1 and the second ends E2 in the circumferential direction. Two wires of each cross wire pair 62, which connect the first end E1 and the second end E2 closest to each other in the circumferential direction to the input nodes of two amplifier circuits 50 disposed outside of the first end E1 and the second end E2, intersect with each other in plan view.

Four input wires 71P are disposed slightly inside of the output wire 71S of the power combining circuit 71. The length of each of the four input wires 71P is approximately one fourth of the length of the output wire 71S. Each of the input wires 71P extends from the output node of one amplifier circuit 50, goes around approximately one fourth of the circumference, and reaches the output node of an adjacent amplifier circuit 50.

Next, an advantageous effect of the eighth embodiment is described.

The input wires 71P and the output wire 71S of the power combining circuit 71 are magnetically coupled to the input wire 61P and the output wires 61S of the power distribution circuit 61. With this configuration, a positive feedback or a negative feedback is applied from the output side to the input side of the differential amplifier circuit including multiple amplifier circuits 50.

When the two wires of each cross wire pair 62 are arranged to intersect with each other, the phase of an electric current flowing through the corresponding input wire 71P of the power combining circuit 71 is reversed. Accordingly, when a condition causing a positive feedback is satisfied by a configuration in which the two wires of each cross wire pair 62 do not intersect with each other, it is possible to apply a negative feedback by arranging the two wires to intersect with each other. Configuring the amplification device such that a negative feedback is applied from the output side to the input side of the amplifier circuits 50 makes it possible to achieve an advantageous effect of suppressing parasitic oscillation resulting from a feedback.

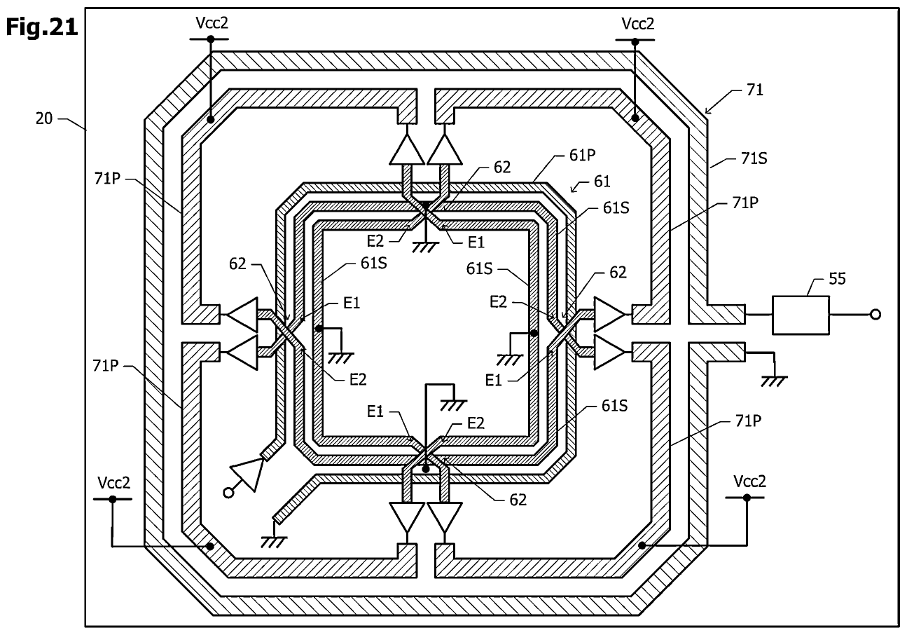

Next, a variation of the eighth embodiment is described with reference to FIG. 21.

FIG. 21 is a schematic diagram illustrating an amplification device according to a variation of the eighth embodiment with a focus on the planar shapes and the positional relationship of the power distribution circuit 61 and the power combining circuit 71. In the eighth embodiment (FIG. 20), the length of each of the four output wires 61S of the power distribution circuit 61 is approximately one fourth of the length of the input wire 61P. In contrast, in this variation, the length of each of the output wires 61S is approximately one half of the length of the input wire 61P. Therefore, the four output wires 61S as a whole go around the circumference approximately two times along the input wire 61P. In FIG. 21, two output wires 61S are disposed inside of other two output wires 61S. However, the two output wires 61S and the other two output wires 61S may be disposed in different wiring layers such that they overlap each other in plan view.

Also in the variation illustrated in FIG. 21, each of the four output wires 61S has the first end E1 and the second end E2. Multiple first ends E1 and multiple second ends E2 are arranged alternately in the circumferential direction. Each pair of the first end E1 and the second end E2 closest to each other in the circumferential direction are connected via the two wires of one of the cross wire pairs 62 to the input nodes of two amplifier circuits 50 that are adjacent to each other in the circumferential direction.

As in this variation, the length of each of the four output wires 61S of the power distribution circuit 61 may be set at approximately one half of the length of the input wire 61P, and the four input wires 61S may be arranged to go around the circumference two times as a whole. The ratio between the length of each output wire 61S and the length of the input wire 61P may be set to any other value. Similarly, the ratio between the length of each of the input wires 71P of the power combining circuit 71 and the length of the output wire 71S may be set to a value other than 1:4.

Next, another variation of the eighth embodiment is described.

In the eighth embodiment, eight amplifier circuits 50 are provided. However, the number of amplifier circuits 50 is not limited to eight. For example, the number of amplifier circuits 50 may be set to four as in the seventh embodiment (FIG. 17) or may be set to any other value greater than one. However, because two input nodes of multiple amplifier circuits 50 are combined to form a differential input node and two output nodes of multiple amplifier circuits 50 are combined to form a differential output node, the number of amplifier circuits 50 is preferably set to an even number.

In the eighth embodiment, the power combining circuit 71 is disposed in or on the substrate 20 formed of a semiconductor. Alternatively, similarly to the variation of the seventh embodiment (FIG. 18), the power combining circuit 71 may be disposed in or on the module substrate 21.

The embodiments described above are examples, and a partial exchange or a combination of components in different embodiments may be made. Descriptions of similar effects provided by different embodiments with similar configurations may be omitted. Furthermore, the present disclosure is not limited to the embodiments described above. For example, a person skilled in the art may understand that various modifications, improvements, and combinations of the embodiments can be made.

What is claimed is:

1. An amplification device comprising:
a substrate;
a first differential amplifier circuit that is in or on the substrate and includes a pair of differential input nodes, which are configured to input differential signals, and a pair of differential output nodes configured to output differential signals;
a first transformer that includes a primary coil and a secondary coil, ends of the secondary coil of the first transformer being connected to the pair of differential input nodes of the first differential amplifier circuit, an intermediate point of the secondary coil of the first transformer being AC grounded;
a second transformer that includes a primary coil and a secondary coil, ends of the primary coil of the second transformer being connected to the pair of differential output nodes of the first differential amplifier circuit, and an intermediate point of the primary coil of the second transformer being AC grounded; and
a differential wire pair that connects the ends of the secondary coil of the first transformer to the pair of differential input nodes of the first differential amplifier circuit, and another differential wire pair connects the pair of differential output nodes of the first differential amplifier circuit to the ends of the primary coil of the second transformer; and
wherein in plan view of the substrate, two wires of one of the differential wire pairs intersect with each other, and two wires of another one of the differential wire pairs do not intersect with each other.

2. The amplification device according to claim 1, wherein
a portion of a magnetic flux generated by the second transformer is interlinked with the first transformer.

3. The amplification device according to claim 1, further comprising:
a single-ended amplifier circuit that is in or on the substrate and is configured to output a single-ended signal, wherein
one end of the primary coil of the first transformer is connected to an output node of the single-ended amplifier circuit, and another end of the primary coil of the first transformer is grounded.

4. The amplification device according to claim 1, further comprising:
a downstream differential amplifier circuit that is in or on the substrate and includes a pair of differential input nodes and a pair of differential output nodes, wherein
ends of the secondary coil of the second transformer are connected to the pair of differential input nodes of the downstream differential amplifier circuit, and an intermediate point of the secondary coil of the second transformer is AC grounded.

5. The amplification device according to claim 1, further comprising:
an upstream differential amplifier circuit that is in or on the substrate and includes a pair of differential input nodes and a pair of differential output nodes; and
ends of the primary coil of the first transformer are connected to the pair of differential output nodes of the upstream differential amplifier circuit, and an intermediate point of the primary coil of the first transformer is AC grounded.

6. The amplification device according to claim 5, further comprising:
an upstream transformer that includes a primary coil and a secondary coil, ends of the secondary coil of the upstream transformer being connected to the pair of differential input nodes of the upstream differential amplifier circuit, and an intermediate point of the secondary coil of the upstream transformer being AC grounded; and
a differential wire pair that connects the ends of the secondary coil of the upstream transformer to the pair of differential input nodes of the upstream differential amplifier circuit, and another differential wire pair connects the pair of differential output nodes of the upstream differential amplifier circuit to the ends of the primary coil of the first transformer, and
wherein in plan view of the substrate, two wires of one of the differential wire pairs intersect with each other, and two wires of another one of the differential wire pairs do not intersect with each other.

7. The amplification device according to claim 1, wherein
the second transformer is in or on the substrate.

8. The amplification device according to claim 1, further comprising:
a module substrate on which the substrate is mounted, wherein
the second transformer is in or on the module substrate.

9. The amplification device according to claim 2, further comprising:
a single-ended amplifier circuit that is in or on the substrate and is configured to output a single-ended signal, wherein
one end of the primary coil of the first transformer is connected to an output node of the single-ended amplifier circuit, and another end of the primary coil of the first transformer is grounded.

10. The amplification device according to claim 2, further comprising:
a downstream differential amplifier circuit that is in or on the substrate and includes a pair of differential input nodes and a pair of differential output nodes, wherein
ends of the secondary coil of the second transformer are connected to the pair of differential input nodes of the downstream differential amplifier circuit, and an intermediate point of the secondary coil of the second transformer is AC grounded.

11. The amplification device according to claim 2, further comprising:
an upstream differential amplifier circuit that is in or on the substrate and includes a pair of differential input nodes and a pair of differential output nodes; and
ends of the primary coil of the first transformer are connected to the pair of differential output nodes of the upstream differential amplifier circuit, and an intermediate point of the primary coil of the first transformer is AC grounded.

12. The amplification device according to claim 2, wherein
the second transformer is in or on the substrate.

13. The amplification device according to claim 3, wherein
the second transformer is in or on the substrate.

14. The amplification device according to claim 4, wherein
the second transformer is in or on the substrate.

15. The amplification device according to claim 2, further comprising:
a module substrate on which the substrate is mounted, wherein
the second transformer is in or on the module substrate.

16. The amplification device according to claim 3, further comprising:
a module substrate on which the substrate is mounted, wherein
the second transformer is in or on the module substrate.

17. The amplification device according to claim 4, further comprising:
a module substrate on which the substrate is mounted, wherein
the second transformer is in or on the module substrate.

18. An amplification device comprising:
a substrate;
multiple amplifier circuits, each of which includes an input node and an output node;
a power distribution circuit that includes one input wire and multiple output wires, one end of the input wire being grounded, a single-ended signal being input to another end of the input wire, an intermediate point of each of the multiple output wires being grounded, the power distribution circuit being configured to output the single-ended signal input to the input wire as differential signals from ends of each of the multiple output wires and to input the differential signals to input nodes of two amplifier circuits selected from the multiple amplifier circuits; and
a power combining circuit configured to combine multiple differential signals output from the multiple amplifier circuits into one single-ended signal, wherein
the multiple output wires of the power distribution circuit are configured along an annular shape in plan view of the substrate;
the multiple amplifier circuits are arranged in a circumferential direction of the annular shape along which the multiple output wires of the power distribution circuit are laid out;
when an upstream end and a downstream end of each of the multiple output wires in one circumferential direction of the annular shape, along which the multiple output wires of the power distribution circuit are laid out, are respectively a first end and a second end, multiple first ends and multiple second ends of the multiple output wires are arranged in the circumferential direction;
the amplification device further comprises multiple cross wire pairs, each of which connects the first end and the second end, which are among the multiple first ends and the multiple second ends and adjacent to each other in the circumferential direction, to two input nodes that are among the input nodes of the multiple amplifier circuits and adjacent to each other in the circumferential direction; and
each of the multiple cross wire pairs includes two wires that intersect with each other in plan view of the substrate.

19. The amplification device according to claim 18, wherein
the power combining circuit is in or on the substrate.

20. The amplification device according to claim 18, further comprising:
a module substrate on which the substrate is mounted, wherein
the power combining circuit is in or on the module substrate.
